(19) United States
(12) Patent Application Publication
(10) Pub. No.: US 2026/0080035 A1
(43) Pub. Date: Mar. 19, 2026

(54) FAST APPROXIMATE ANALYSIS METHOD FOR MUTUAL COUPLING-CONTAINING PATTERN OF A LARGE-SCALE ULTRA-WIDEBAND HETEROGENEOUS ARRAY

(71) Applicant: UNIVERSITY OF ELECTRONIC SCIENCE AND TECHNOLOGY OF CHINA, Chengdu (CN)

(72) Inventors: Yanhui LIU, Chengdu (CN); Liyang CHEN, Chengdu (CN); Pan WU, Chengdu (CN); Xianzheng ZONG, Chengdu (CN); Shiwen YANG, Chengdu (CN); Jun HU, Chengdu (CN); Zaiping NIE, Chengdu (CN)

(21) Appl. No.: 19/127,444

(22) PCT Filed: May 29, 2024
(86) PCT No.: PCT/CN2024/096004

§ 371 Date: May 6, 2025

(30) Foreign Application Priority Data
Jun. 28, 2023 (CN) 202310774967.4

(51) Int. Cl. G06F 18/241; G06F 17/11; G06F 30/20; H01Q 21/24

(52) U.S. Cl. CPC G06F 18/241; G06F 17/11; G06F 30/20; H01Q 21/24

(57) ABSTRACT

The present disclosure discloses a fast approximate analysis method for mutual coupling-containing pattern of a large-scale ultra-wideband heterogeneous array, comprises: dividing the entire large-scale ultra-wideband heterogeneous array into a plurality of sub-arrays according to a type of element used by a heterogeneous array, ensuring that each sub-array contains elements of the same type; classifying the elements in the sub-arrays; selecting representative elements for representing environmentally similar elements, removing rows and columns that do not have the representative elements, and retaining all key features of the heterogeneous array; performing full-wave simulation on a constructed compact representative array, extracting AEPs of all the representative elements, and storing same; and replacing AEPs of the environmentally similar elements with the AEPs of the representative elements, performing approximate computing to obtain patterns of all the sub-arrays, and superimposing the obtained results to obtain a mutual-coupling-containing pattern of the heterogeneous array.

### CROSS-REFERENCE TO RELATED APPLICATION

This application claims priority to Chinese Patent Application No. 202310774967.4, filed with the China National Intellectual Property Administration on Jun. 28, 2023, the entirety of which is incorporated herein by reference.

### TECHNICAL FIELD

This application relates to the field of array antennas, and in particular, to a fast approximate analysis method for mutual coupling-containing pattern of a large-scale ultra-wideband heterogeneous array.

### BACKGROUND

In solving most array synthesis problems, a pattern multiplication theorem is commonly used to represent a array pattern as a multiplication of an element pattern and an array factor. Once the array factor is synthesized to meet design requirements, it is multiplied by the element pattern to generate the desired array pattern. However, in a practical environment, antenna element can not exist in isolation. Structures surrounding the elements absorb and reflect electromagnetic waves, so that a radiation pattern of the antenna element is influenced. Mutual coupling refers to the interaction between the antenna element and its surrounding environment, which is mainly influenced by three factors: 1) coupling between adjacent elements, 2) coupling due to interactions with nearby conductors, and 3) coupling within the array's feed network. The presence of mutual coupling introduces discrepancies between the array patterns calculated using the pattern multiplication theorem and the actual array patterns, leading to synthesized patterns that fail to meet the required radiation performance. Therefore, for heterogeneous arrays where the mutual coupling effect is complex, it is necessary to consider the mutual coupling effect in synthesis and design of the large-scale ultra-wideband heterogeneous array to improve accuracy.

For the synthesis of the array containing the mutual coupling, in theory, full-wave simulations are required to obtain an active element pattern (AEP) for each element. The AEP is then integrated into a synthesis algorithm to obtain a feed excitation amplitude and phase to meet radiation index under the condition of the mutual coupling effect. In the final step, the AEP is weighted by the feed excitation values and summed to generate the mutual coupling-aware array pattern. However, when dealing with arrays that contain numerous elements and operate over a wide bandwidth, the complexity of analyzing the mutual coupling-aware pattern increases significantly due to the following factors:

High complexity of the full-wave simulation: a simulation process involves calculating the electromagnetic radiation characteristics of each element in the far field. And because of the large scale of a given array, a large number of element characteristic parameters exist, so that the computational complexity of full-wave simulations grows exponentially, and even the full-wave simulation cannot be solved.

Large storage requirements of the full-wave simulation: the simulation process requires storing the AEP data for each element. The given array with the wide bandwidth and the high angular resolution, a vast amount of pattern data is generated, leading to significant storage overhead for the full-wave simulation.

In conclusion, directly performing the full-wave simulations on the large-scale ultra-wideband heterogeneous array while considering mutual coupling effects is impractical. Hence, it is a necessary to develop a fast analysis method for the mutual coupling-containing pattern of the large-scale ultra-wideband heterogeneous array, so as to greatly reduce the cost of required computational time and computational storage.

Patent CN201410298622.7 provides a method for analyzing the sidelobe performance of large heterogeneous arrays with mutual coupling consideration. This method constructs the coupling matrix of the entire array utilizing the coupling matrices of sub-arrays, allowing for the analysis of structural errors and mutual coupling effects on array performance. While this method effectively solves the problem which the mutual coupling effect on the heterogeneous array antenna is difficult to evaluate in the prior art. However the mutual coupling analysis method still requires full-wave simulations of the entire array, resulting in significant simulation computational resource demands for large-scale arrays.

Patent CN202210710497.0 provides a fast and precise analysis method of a vector gain pattern of an irregular antenna array. This methods involves a series of operations on the vector active element pattern of the representative element in the irregular antenna array, including rotation, interpolation, translation, and projection, enabling rapid and accurate analysis of the vector gain pattern of the irregular antenna array. As a result, it significantly reduces the simulation time of the full-wave simulation for a large-scale irregular array. However, this mutual coupling analysis method is limited to standard irregular array and is not suitable for more complex heterogeneous array.

### SUMMARY

The objective of this application is to address the limitations of existing mutual coupling analysis methods by introducing a fast analysis method for mutual coupling-containing pattern of a large-scale ultra-wideband heterogeneous array. This method constructs a compact representative array that retains key features of the original large-scale heterogeneous array, effectively avoids huge operation resource expenditure of the full-wave simulation of the large-scale heterogeneous array, greatly reduces the complexity of calculation of the mutual coupling-containing pattern, and can ensure the accuracy of the obtained mutual coupling-containing pattern.

This application discloses a rapid analysis method for a cross coupling pattern of a large-scale ultra-wideband heterogeneous array, which comprises the following steps:
step 1: dividing the entire large-scale ultra-wideband heterogeneous array into a plurality of sub-arrays according to a type of element used by a heterogeneous array, ensuring that each sub-array contains elements of the same type;
step 2: classifying elements within each sub-array into corner elements, edge elements, and internal elements based on a position of a array unit;
step 3: For elements in similar environments, an active element pattern (AEP) of representative elements is selected for characterization, the active element pattern includes corner representative elements, edge representative elements, and internal representative elements;
step 4: Based on the selected representative elements, performing a compact reconfiguration of the heterogeneous array, removing rows and columns which do not contain representative elements, and retaining all key features of the heterogeneous array;
step 5: a full-wave simulation is carried out on a constructed compact representative array, and the AEP data of all representative elements from a simulation result is extracted and stored; and
step 6: the AEP of similar elements in the array environment is replaced by the AEP of the representative elements to approximately calculate a pattern of each sub-array, and then superimpose the results to obtain a mutual coupling-aware pattern of the heterogeneous array.

This application offers the following advantages and beneficial effects:
a) This application divides the large-scale ultra-wideband heterogeneous array into sub-arrays and classifies the elements within each sub-array based on the type of the element of the heterogeneous array and the array position of the element, thereby clarifying the constitution of each part of the heterogeneous array and guiding the selection of representative units.
b) This application performs compact recombination on the large-scale heterogeneous array based on the representative unit, and clarifies the basic array structure for describing all key characteristics of the heterogeneous array, thereby converting the full-wave simulation on the large-scale heterogeneous array into full-wave simulation on the small-scale compact representative array, and effectively avoiding huge computing resource expenditure of the full-wave simulation.
c) The application uses the AEP of the representative element to replace the AEP of the similar element of the array environment, so that the calculation of the directional diagram containing the mutual coupling can use the directional diagram product theorem, thereby greatly reducing the calculation complexity.
d) According to this application, a plurality of representative units, including the corner representative elements, the edge representative elements and the internal representative elements, are used instead of a single representative element, so that complex mutual coupling conditions of the heterogeneous array can be better represented, and high accuracy of approximate operation of the heterogeneous array containing mutual coupling patterns is ensured.

### BRIEF DESCRIPTION OF DRAWINGS

The accompanying drawings, which are included to provide a further understanding of embodiments of the application and are incorporated in and constitute a part of this specification, illustrate embodiments of the application and together with the description serve to explain the principles of the application. In the drawings:

FIG. 1 is a flow chart of the method of this application;

FIG. 2 is a schematic diagram of the large-scale ultra-wideband heterogeneous array model of this application;

FIG. 3 is a schematic diagram of a representative element of the large-scale ultra-wideband heterogeneous array of this application;

FIG. 4 is a schematic diagram of the large-scale ultra-wideband heterogeneous array of this application with non-critical feature rows removed; and

FIG. 5 is a schematic diagram of the large-scale ultra-wideband heterogeneous array of this application with non-critical feature columns removed, i.e., a schematic diagram of a small-scale compact representative array of the large-scale ultra-wideband heterogeneous array.

### DESCRIPTION OF EMBODIMENTS

Before detailing any specific embodiment of this invention, it is important to note that the application of the invention is not limited to the structures described below or shown in the accompanying figures. The invention may be implemented in other contexts and can be executed in various approaches. Any other embodiments that those skilled in the art may derive, without inventive modifications, based on the described embodiments, are considered to fall within the scope of this invention.

The large-scale ultra-wideband heterogeneous array refer to antenna array which is composed of a large number (usually including hundreds or even more) of different types and different performance antenna elements that can cover a very wide operating frequency band.

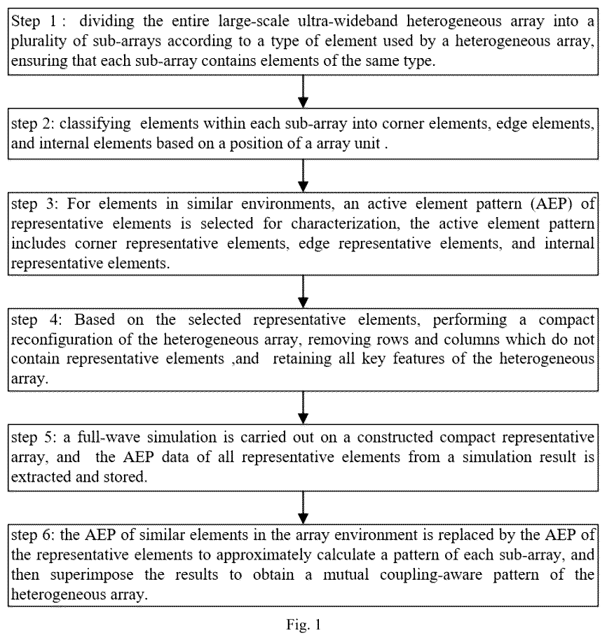

As shown in FIG. 1, this application includes the steps of:
Sub-array division of the heterogeneous array;

For the application requirements of ultra-wideband, the large-scale heterogeneous array generally needs to use various antenna units working in specific frequency bands, and the advantages of various units are fully utilized. In addition, to increase aperture efficiency and array gain, the heterogeneous array sub-arrays are typically arranged in a uniformly spaced arrangement. The entire large-scale heterogeneous array may be divided into a plurality of sub-arrays, each of which has the same cell type, according to the cell type used. After sub-array division, the array pattern of the heterogeneous array can be expressed as:

$$F ( θ , φ , f ) = {\sum }_{k = 1}^{K} {F}_{s u b}^{( k )} ( θ , φ , f ) \qquad ( 1 )$$

where θ is the zenith angle, φ is the azimuth angle, f is the operating frequency,

$${F}_{sub}^{( k )} ( θ , φ , f )$$

represents the array pattern of the k-th sub-array, and K is the total number of sub-arrays. The array pattern of the k-th sub-array can be expressed as:

$${F}_{s u b}^{( k )} ( θ , φ , j ) = {\sum }_{n ∈ {S}^{( k )}} {w}_{n} {g}_{n} ( θ , φ , j ) {e}^{j β {\vec{r}}_{n} \cdot \vec{a} ( θ , φ )} \qquad ( 2 )$$

where S^{(k)} represents the set of element indices for the k-th sub-array, and n wₙ represents the excitation of the n-th element excitation. β=2πf/c represents the wavenumber in free space at the operating frequency f, where c is the velocity of wave propagation in free space. \vec{r}ₙ=(xₙ,yₙ) represents the position vector of the n-th element on the XOY plane (the plane in the Cartesian coordinate system), ā(θ,φ)=(sin θ cos φ,sin θ sin φ) represents the propagation vector, and gₙ(θ,φ,f) represents the AEP of the n-th element at the operating frequency f.

Classifying large-scale heterogeneous array units;

Within the divided sub-arrays, the elements can be classified based on their positions in the array as corner elements, edge elements, and internal elements. These separately correspond to the sets C^{(k)}, E^{(k)}, and I^{(k)}, where C^{(k)}∩E^{(k)}∩I^{(k)}=Ø and C^{(k)}∪E^{(k)}∪I^{(k)}=S^{(k)}. Therefore, the array pattern for the k-th sub-array can be further expressed as:

$${F}_{sub}^{( k )} ( θ , φ , f ) = {\sum }_{n ∈ {C}^{( k )}} {w}_{n} {g}_{n} ( θ , φ , f ) {e}^{j β {\vec{r}}_{n} \cdot \vec{a} ( θ , φ )} + {\sum }_{n ∈ {E}^{( k )}} {w}_{n} {g}_{n} ( θ , φ , f ) {e}^{j β {\vec{r}}_{n} \cdot \vec{a} ( θ , φ )} + {\sum }_{n ∈ {I}^{( k )}} {w}_{n} {g}_{n} ( θ , φ , f ) {e}^{j β {\vec{r}}_{n} \cdot \vec{a} ( θ , φ )} \qquad ( 3 )$$

Selecting a representative unit of the large-scale heterogeneous array;

The array environment of each element determines its mutual coupling and platform effects, which directly influence the characteristics of the AEP of the element. In the case of a uniformly spaced layout, many elements share similar array environments and, consequently, similar AEPs. Therefore, the AEPs of these elements in smilar srray environments can be replaced with the AEPs of those of representative elements, thereby utilizing the pattern product theorem to accelerate the computation of the array pattern. The representative cells corresponding to the corner elements, the edge elements, and the inside elements are referred to as corner representative elements, edge representative elements, and inside representative elements, respectively. For the corner elements, the array environment where each element is located is quite different, and it is difficult to select representative element for unified characterization, so that a typical corner representative element is the corner element itself. For edge elements, the array environment difference between edges is larger, but the array environment of the elements in each edge region are closer, so that the edge representative element can be used for unified characterization. For internal elements, the array environments of the elements are relatively close, so that the internal representative element can be used for unified characterization. It is recommended to select each regional center unit as a representative element and locate the representative element in the same row or column as much as possible to facilitate compact reorganization of subsequent large-scale heterogeneous array.

Compact reorganization of the large-scale heterogeneous array;

The selection of representative elements of the large-scale heterogeneous array establishes the basic “skeleton” of the heterogeneous array, defining a fundamental structure that retains key characteristics of the large-scale heterogeneous array. Compact reorganization can be performed on a large-scale heterogeneous array without missing key features. The rows and columns in which the representative elements are located are referred to as critical feature rows and columns of the heterogeneous array. Firstly, eliminating non-key characteristic rows of the heterogeneous array; second, non-critical feature columns of the heterogeneous array are culled. Through the above operations, a compact representative array is obtained that retains all of the key features of the large scale heterogeneous array.

### Full-Wave Simulation of the Compact Representative Array

Full-wave simulations are performed on a small-scale compact representative array of the large-scale heterogeneous array, and the AEP data for all representative elements in a simulation result, including corner representative elements AEP, edge representative elements AEP and internal representative elements AEP, is extracted and stored. Full-wave simulation is carried out on the compact representative array, and huge operation resource cost caused by direct full-wave simulation on the whole large-scale ultra-wideband heterogeneous array can be effectively avoided.

### Approximate Calculation of Mutual Coupling-Containing Pattern

Based on the obtained AEP data for the representative elements, the AEP of the similar element of the array environment is replaced by the AEP of the representative unit. The array patterns for all sub-arrays are then calculated by the following approximate expression (where

$$\{ {F}_{sub}^{( k )} ( θ , φ , f ) ; \vert k = 1 , 2 , … , K \} ) :$$

$${F}_{sub}^{( k )} ( θ , φ , f ) \approx {\sum }_{n ∈ {C}^{( k )}} {w}_{n} {g}_{n} ( θ , φ , f ) {e}^{j β {\vec{r}}_{n} \cdot \vec{a} ( θ , φ )} + {{\sum }^{P}}_{p = 1} {\hat{g}}_{{E}_{p}^{( k )}} ( θ , φ , f ) {\sum }_{n ∈ {E}_{p}^{( k )}} {w}_{n} {e}^{j β {\vec{r}}_{n} \cdot \vec{a} ( θ , φ )} + {\hat{g}}_{{I}^{( k )}} ( θ , φ , f ) {\sum }_{n ∈ {I}^{( k )}} {w}_{n} {e}^{j β {\vec{r}}_{n} \cdot \vec{a} ( θ , φ )} \qquad ( 4 )$$

where,

$${\hat{g}}_{{E}_{p}^{( k )}} ( θ , φ , f )$$

is the AEP of the representative element along the p-th edge of the k-th sub-array,

$${E}_{p}^{( k )}$$

is the corresponding set of elements along the p-th edge of the k-th sub-array, with

$${E}^{( k )} = \{ {E}_{p}^{( k )} ; \vert p = 1 , 2 , … , P \} .$$

ĝ₍ₖ₎(θ,φ,f) is the AEP of the representative element inside the k-th sub-array. Clearly, the approximate calculation of the sub-array patterns can utilize the pattern multiplication theorem, significantly reducing computational complexity. Finally, the array patterns of all sub-arrays are superimposed to obtain the mutual coupling-containing pattern of the entire large-scale heterogeneous array, namely

$$F ( θ , φ , f ) = {\sum }_{k = 1}^{K} {F}_{sub}^{( k )} ( θ , φ , f ) .$$

### Embodiment

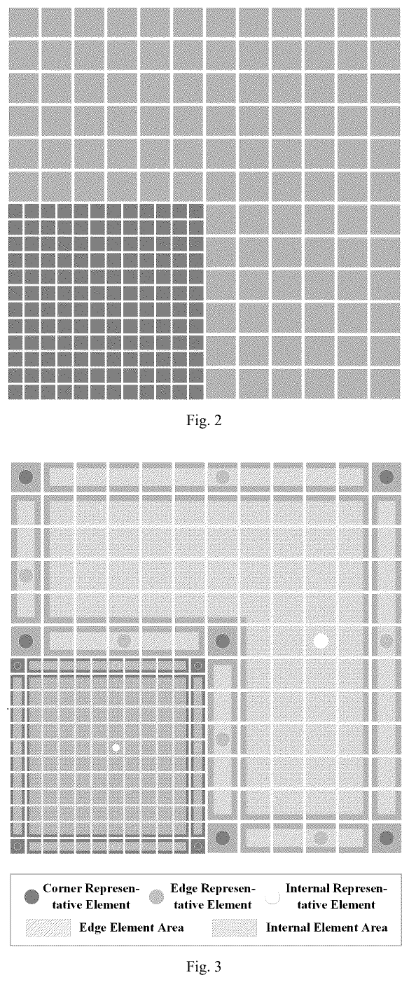

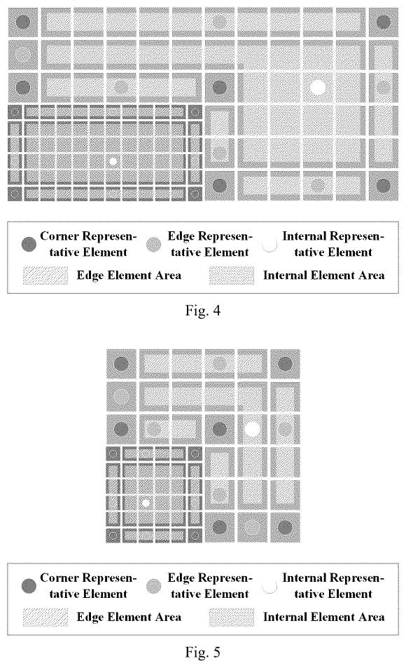

As illustrated in FIG. 2, the large-scale ultra-wideband heterogeneous array is composed of two nested sub-arrays, shown in light gray and dark gray. The light gray sub-array contains 108 elements, while the dark gray sub-array consists of 144 elements, totaling 252 elements. The elements are classified according to their positions within the sub-arrays: the corner elements are located at the vertices, and the edge elements and the internal elements are high lighted in FIG. 3 (within the edge and internal element areas). The corner representative elements are selected from the corner elements themselves, while one representative element is chosen for both the edge and internal areas. The selection follows the principle of choosing elements located centrally within their area and, when possible, aligning them in the same row or column. The selected representative elements are depicted in FIG. 3. Using these representative elements, the large-scale heterogeneous array undergoes compact reconfiguration. First, non-key feature rows are removed, as shown in FIG. 4. Then, non-key feature columns are removed, resulting in the compact representative array displayed in FIG. 5. This compact array retains all the key features of the original large-scale array, using only 21 light gray elements and 16 dark gray elements, for a total of 37 elements-just 14.7% of the original large-scale array. Full-wave simulations are conducted on this compact array, and the AEP datas of all representative elements are extracted. The AEPs of the representative elements are then used to replace the AEPs of the corresponding elements in their regions, and the sub-array patterns are calculated approximately. These results are then combined to produce the mutual coupling-containing pattern for the entire large-scale ultra-wideband heterogeneous array.

FIGS. 2 and 5 clearly demonstrate that the compact representative array is significantly smaller than the original heterogeneous array, which greatly reduces the computational resources required for full-wave simulations. In contrast to simulating the entire large-scale heterogeneous array, the compact representative array demands far fewer resources. Meanwhile, as replacement of a representative element AEP is introduced, the calculation of the mutual coupling-containing pattern can use the directional diagram product theorem, so that the calculation complexity is greatly reduced. In summary, compared with no approximation processing, namely full-wave simulation and superposition calculation of the cross-coupling directional diagram directly on the large-scale ultra-wideband heterogeneous array, the proposed method can remarkably reduce the expenditure of operation resources and the calculation complexity. In addition, the proposed method can more accurately describe the true mutual coupling effect using multi-representative elements than using single representative element, and is more suitable for the large-scale heterogeneous array with complex geometries. Although adding the representative elements to a certain extent expands the scale of the compact representative array and thus increases the computation amount of the full-wave simulation, the computation resource overhead of this part is necessary to ensure the accuracy of the obtained cross-coupling pattern.

What is claimed is:

1. A fast approximate analysis method for mutual coupling-containing pattern of a large-scale ultra-wideband heterogeneous array, comprising:
step 1: dividing the entire large-scale ultra-wideband heterogeneous array into a plurality of sub-arrays according to a type of element used by a heterogeneous array, ensuring that each sub-array contains elements of the same type;
step 2: classifying elements within each sub-array into corner elements, edge elements, and internal elements based on a position of a array unit;
step 3: For elements in similar environments, an active element pattern (AEP) of representative elements is selected for characterization, the active element pattern includes corner representative elements, edge representative elements, and internal representative elements;
step 4: Based on the selected representative elements, performing a compact reconfiguration of the heterogeneous array, removing rows and columns which do not contain representative elements, and retaining all key features of the heterogeneous array;
step 5: a full-wave simulation is carried out on a constructed compact representative array, and the AEP data of all representative elements from a simulation result is extracted and stored; and
step 6: the AEP of similar elements in the array environment is replaced by the AEP of the representative elements to approximately calculate a pattern of each sub-array, and then superimpose the results to obtain a mutual coupling-aware pattern of the heterogeneous array.

2. The fast approximate analysis method for mutual coupling-containing pattern of a large-scale ultra-wideband heterogeneous array according to claim 1, wherein in the step 1 and step 2, sub-array division and the elements within sub-array classification are carried out on the heterogeneous array so as to clarify the constitution of each part of the heterogeneous array, and establish a standardized mathematical model, Wherein patterns of the heterogeneous array and its sub-arrays can be specifically expressed as:
$$\begin{matrix}F ( θ , φ , f ) = {\sum }_{k = 1}^{K} {F}_{sub}^{( k )} ( θ , φ , f ) \\ {F}_{sub}^{( k )} ( θ , φ , f ) = {\sum }_{n ∈ {S}^{( k )}} {w}_{n} {g}_{n} ( θ , φ , f ) {e}^{j β {\vec{r}}_{n} \cdot \vec{a} ( θ , φ )}\end{matrix}$$
Wherein θ is a zenith angle, φ is an azimuth angle, and f is an operating frequency, S^{(k)} represents a set of element indices for the k-th sub-array, with K being a total number of subarrays, wₙ denotes a n-th element excitation, and β=2πf/c represents a wavenumber in free space at f, where c is a velocity of wave propagation in free space, r̅ₙ=(xₙ,yₙ) represents the n-th element's position vector on the XOY plane, ā(θ,φ)=(sin θ cos φ,sin θ sin φ) represents a propagation vector, gₙ(θ,φ,f) represents the AEP of the n-th element operating at a frequency point, denotes
$${F}_{sub}^{( k )} ( θ , φ , f )$$
denotes the pattern of the k-th sub-array, and F(θ,φ,f) is the pattern of the entire heterogeneous array; after classifying the sub-array elements into corner elements, edge elements, and internal elements, the sub-array pattern can be expressed as follows:
$${F}_{sub}^{( k )} ( θ , φ , f ) = {\sum }_{n ∈ {C}^{( k )}} {w}_{n} {g}_{n} ( θ , φ , f ) {e}^{j β {\vec{r}}_{n} \cdot \vec{a} ( θ , φ )} + {\sum }_{n ∈ {E}^{( k )}} {w}_{n} {g}_{n} ( θ , φ , f ) {e}^{j β {\vec{r}}_{n} \cdot \vec{a} ( θ , φ )} + {\sum }_{n ∈ {I}^{( k )}} {w}_{n} {g}_{n} ( θ , φ , f ) {e}^{j β {\vec{r}}_{n} \cdot \vec{a} ( θ , φ )}$$
wherein C^{(k)}, E^{(k)}, and I^{(k)} represent the sets of the corner elements, the edge elements, and the internal elements, respectively.

3. The fast approximate analysis method for mutual coupling-containing pattern of a large-scale ultra-wideband heterogeneous array according to claim 1, wherein in the step 3, a plurality of representative elements are selected to represent the corner elements, the edge elements, and the internal elements, rather than using a single representative element, so that the complex mutual coupling of the heterogeneous array can be characterized more accurately.

4. The fast approximate analysis method for mutual coupling-containing pattern of a large-scale ultra-wideband heterogeneous array according to claim 1, wherein in the step 4, the compact reconfiguration of a given heterogeneous array is performed based on the selected representative elements, removing rows and columns which do not contain representative elements, resulting in a simplified array structure which retains all key features.

5. The fast approximate analysis method for mutual coupling-containing pattern of a large-scale ultra-wideband heterogeneous array according to claim 1, wherein in the step 5, the full-wave simulation is performed on the compact representative array, so that huge computing resource cost of full-wave simulation of the entire large-scale ultra-wideband heterogeneous array can be effectively avoided, and essential key characteristic of the heterogeneous array, namely the AEP data of the representative elements, can be obtained.

6. The fast approximate analysis method for mutual coupling-containing pattern of a large-scale ultra-wideband heterogeneous array according to claim 1, wherein in the step 6, the AEPs of the representative elements are used to replace the AEPs of array elements in the similar environments, and the patterns of all sub-arrays can then be calculated using the following approximate expression:
$${F}_{sub}^{( k )} ( θ , φ , f ) \approx {\sum }_{n ∈ {C}^{( k )}} {w}_{n} {g}_{n} ( θ , φ , f ) {e}^{j β {\vec{r}}_{n} \cdot \vec{a} ( θ , φ )} + {{\sum }^{P}}_{p = 1} {\hat{g}}_{{E}_{p}^{( k )}} ( θ , φ , f ) {\sum }_{n ∈ {E}_{p}^{( k )}} {w}_{n} {e}^{j β {\vec{r}}_{n} \cdot \vec{a} ( θ , φ )} + {\hat{g}}_{{I}^{( k )}} ( θ , φ , f ) {\sum }_{n ∈ {I}^{( k )}} {w}_{n} {e}^{j β {\vec{r}}_{n} \cdot \vec{a} ( θ , φ )}$$
wherein θ is the zenith angle, φ is the azimuth angle, and f is the operating frequency, β=2πf/c represents the wavenumber in free space at frequency f, where c is the velocity of wave propagation in free space, \vec{r}ₙ=(xₙ,yₙ) represents the n-th element's position vector on the XOY plane, and \vec{a}(θ,φ)=(sin θ cos φ, sin θ sin φ) represents the propagation vector, gₙ(θ,φ,f) represents the AEP of the n-th element operating at a frequency point,
$${\hat{g}}_{{E}_{p}^{( k )}} ( θ , φ , f )$$
is the representative element's AEP along the p-th edge of the k-th sub-array, and
$${E}_{p}^{( k )}$$
is the corresponding set of elements:
$${E}^{( k )} = \{ {E}_{p}^{( k )} ; \vert p = 1 , 2 , … , P \} ,$$
where P is the total number of edges, g_{I}_{^{(k)}}(θ,φ,f) is the representative element's AEP inside the k-th sub-array, and C^{(k)}, E^{(k)}, and I^{(k)} represent the sets of corner elements, edge elements, and internal elements, respectively; after superimposing the results, the pattern with mutual coupling-aware of the heterogeneous array is obtained; and because of the introduction of replacement of the AEP of the representative element, the calculation can leverage the pattern multiplication theorem, significantly reducing the complexity of computing the mutual coupling-aware pattern.
